(19) United States
(12) Patent Application Publication
(10) Pub. No.: US 2021/0063450 A1
(43) Pub. Date: Mar. 4, 2021

(54) SYSTEM FOR PRECISION MEASUREMENT OF ELECTRICAL CURRENT

(71) Applicant: TRIPLE WIN TECHNOLOGY(SHENZHEN) CO.LTD., Shenzhen (CN)

(72) Inventor: YU-AN CHO, New Taipei (TW)

(21) Appl. No.: 16/567,310

(22) Filed: Sep. 11, 2019

(30) Foreign Application Priority Data
Aug. 28, 2019 (CN) 201910804361.4

(51) Int. Cl. G01R 19/22; G01R 19/00

(52) U.S. Cl. CPC G01R 19/22; H02M 7/003; G01R 19/0023

(57) ABSTRACT

A system for precise measurement of current takes current from a current input terminal, the system includes a controlling unit, a voltage generating unit, a voltage amplifying unit, and a processing unit. After sampling the current, the controlling unit outputs a control signal to the voltage generating unit. The voltage generating unit converts the current into different voltage signals. The voltage amplifying unit amplifies the voltage signal, and outputs the amplified signal to the processing unit. The processing unit converts the amplified voltage signal to obtain a corresponding value of current. The system accurately measures currents of different magnitudes, and improves the accuracy of current detection.

### FIELD

The subject matter herein generally relates to measurement of electricity.

### BACKGROUND

In general, a current detecting circuit mainly uses a current detecting chip to measure the current. However, in practical applications, a current detecting chip can limit the accuracy of the current detecting.

Therefore, there is a room for improvement.

### BRIEF DESCRIPTION OF THE DRAWINGS

Implementations of the present disclosure will now be described, by way of embodiments, with reference to the attached figures.

FIG. 1 is a block diagram of an embodiment of a current measurement system.

FIG. 2 is a block diagram of another embodiment of a current measurement system.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series, and the like.

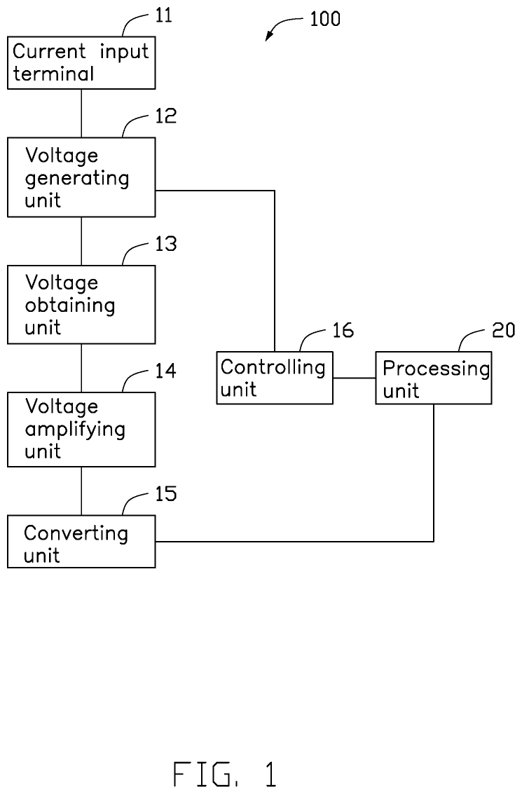

FIG. 1 illustrates a current measurement system 100 in accordance with an embodiment of the present disclosure. The current measurement system 100 is configured to measure current at a current input terminal 11.

In at least one embodiment, the current measurement system 100 includes a voltage generating unit 12, a voltage obtaining unit 13, a voltage amplifying unit 14, a converting unit 15, a controlling unit 16, and a processing unit 20.

The voltage generating unit 12 is electrically coupled to the current input terminal 11. The voltage generating unit 12 receives the current from the current input terminal 11.

The voltage generating unit 12 is electrically coupled to controlling unit 16. The voltage generating unit 12 receives the control signal from the controlling unit 16, and converts the magnitude of the current into different voltage signals.

The voltage obtaining unit 13 is electrically coupled between the voltage generating unit 12 and voltage amplifying unit 14.

The voltage obtaining unit 13 obtains the voltage signals, and transmits the voltage signals to the voltage amplifying unit 14.

The voltage amplifying unit 14 is electrically coupled between the voltage obtaining unit 13 and the converting unit 15. The voltage amplifying unit 14 amplifies the voltage signal by a preset coefficient, and outputs the amplified voltage signal to the converting unit 15.

The converting unit 15 is electrically coupled to processing unit 20. The converting unit 15 performs analog-to-digital conversion on the amplified voltage signal to obtain a digital signal, and outputs the digital signal to the processing unit 20.

The processing unit 20 selects a magnification according to the digital signal to obtain a corresponding value of current.

In at least one embodiment, the processing unit 20 may include a human-computer interface platform and a computer.

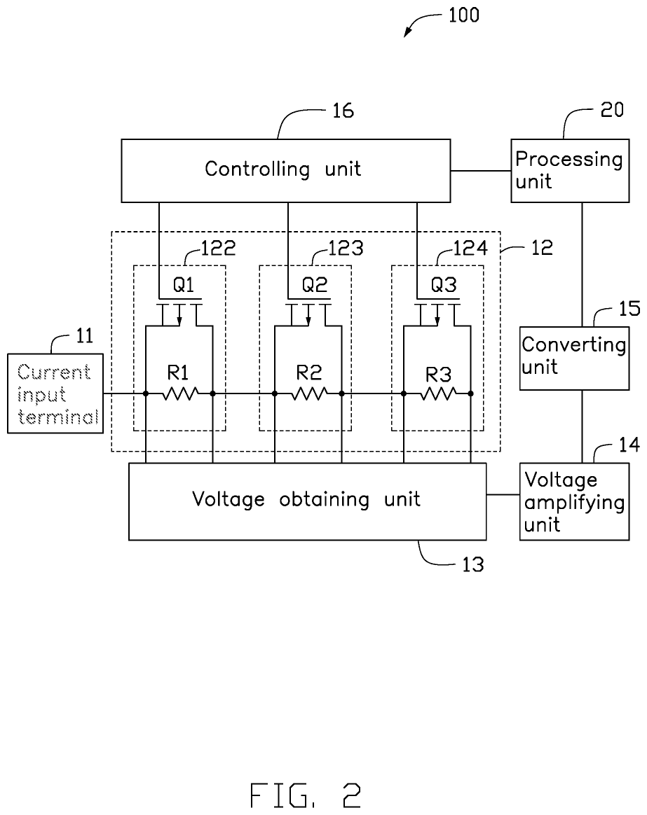

FIG. 2 illustrates the voltage generating unit 12 includes a plurality of switch controlling modules. The switch controlling modules are electrically coupled to the controlling unit 16.

In the embodiment, the voltage generating unit 12 shows only three switch controlling modules (switch controlling module 122, switch controlling module 123, and switch controlling module 124) as an example. In other embodiments, the number of the switch controlling modules in the voltage generating unit 12 may also be greater than three.

In the embodiment, the switch controlling module 122 includes a switch Q1 and a resistor R1. The switch controlling module 123 includes a switch Q2 and a resistor R2. The switch controlling module 124 includes a switch Q3 and a resistor R3.

A first terminal of the switch Q1 is electrically coupled to the controlling unit 16. A second terminal of the switch Q1 is electrically coupled to the current input terminal 11, and the second terminal of the switch Q1 is electrically coupled to a first terminal of the resistor R1. A third terminal of the switch Q1 is electrically coupled to a second terminal of the resistor R1. The first terminal and the second terminal of the resistor R1 are electrically coupled to the voltage obtaining unit 13.

A first terminal of the switch Q2 is electrically coupled to the controlling unit 16. A second terminal of the switch Q2 is electrically coupled to a first terminal of the resistor R2. A third terminal of the switch Q2 is electrically coupled to a second terminal of the resistor R2. The second terminal of the resistor R1 is electrically coupled to the first terminal of the resistor R2. The first terminal and the second terminal of the resistor R2 are electrically coupled to the voltage obtaining unit 13.

A first terminal of the switch Q3 is electrically coupled to the controlling unit 16. A second terminal of the switch Q3 is electrically coupled to a first terminal of the resistor R3. A third terminal of the switch Q3 is electrically coupled to a second terminal of the resistor R3. The second terminal of the resistor R2 is electrically coupled to the first terminal of the resistor R3. The first terminal and the second terminal of the resistor R3 are electrically coupled to the voltage obtaining unit 13.

In at least one embodiment, the switch Q1, the switch Q2, and the switch Q3 can be field effect transistors (FET). The first terminal of the switch Q1, the switch Q2, and the switch Q3 can be gates of the FETs, the second terminal of the switch Q1, the switch Q2, and the switch Q3 can be drains of the FETs, and the third terminal of the switch Q1, the switch Q2, and the switch Q3 can be sources of the FETs.

In at least one embodiment, the resistances of the resistor R1, the resistor R2, and the resistor R3 are all different. For example, the resistance of the resistor R1 is 0.1 ohm, the resistance of the resistor R2 is 0.01 ohm, and the resistance of the resistor R3 is 1 ohm.

In use, the current input terminal 11 inputs current, and the processing unit 20 outputs a switch signal to the voltage generating unit 12 according to the initialized setting, to obtain a current signal. The processing unit 20 determines the magnitude of the current signal.

If the processing unit 20 cannot determine the magnitude of the current signal, the processing unit 20 sends an instruction signal to the controlling unit 16. The controlling unit 16 selects a resistor (such as R1) corresponding to the apparent magnitude of the current signal according to the command signal, and outputs the control signal at a first level to the first end of the switch corresponding to the resistor (such as the switch Q1), so that the switch Q1 is turned off. At the same time, the controlling unit 16 outputs the control signal at a second level to the first end of the switch Q2 and the switch Q3, so that the switch Q2 and the switch Q3 are turned on.

Thereby, the current signal generated by the current input terminal 11 passes through the resistor R1 only. At this time, the voltage obtaining unit 13 acquires a voltage signal of both ends of the resistor R1, and outputs the voltage signal to the voltage amplifying unit 14. The voltage amplifying unit 14 amplifies the voltage signal with a preset amplification factor A (such as 1000 times), and transmits the amplified voltage signal to the converting unit 15.

The converting unit 15 performs analog-to-digital conversion on the amplified voltage signal to obtain the digital signal, and outputs the digital signal to the processing unit 20. The processing unit 20 selects a magnification according to the digital signal to obtain a current value.

Since the resistance values of the resistors are all different, the processing unit 20 will control the conduction states corresponding to the switches Q1-Q3 according to the magnitude of the current signal.

Similarly, the controlling unit 16 controls the current signal input by the current input terminal 11 to pass through all or one other resistor on the same principle as that applied to the resistor R1.

Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the exemplary embodiments described above may be modified within the scope of the claims.

What is claimed is:

1. A current measurement system configured for measuring current at a current input terminal, comprising:
a controlling unit outputting a control signal;
a voltage generating unit coupling the controlling unit and the current input terminal; wherein the voltage generating unit receives the control signal, and converts the current into different voltage signals;
a voltage amplifying unit coupling the voltage generating unit, and amplifying the voltage signals by a preset coefficient to obtain an amplified voltage signal; and
a processing unit coupling the voltage amplifying unit, and converting the amplified voltage signal to obtain a corresponding value of current.

2. The current measurement system of claim 1, wherein the current measurement system further comprises a voltage obtaining unit, the voltage obtaining unit is electrically coupled between the voltage generating unit and the voltage amplifying unit, and the voltage obtaining unit obtains the voltage signals from the voltage generating unit, and transmits the voltage signals to the voltage amplifying unit.

3. The current measurement system of claim 2, wherein the current measurement system further comprises a converting unit, the converting unit is electrically coupled between the voltage amplifying unit and the processing unit.

4. The current measurement system of claim 3, wherein the converting unit performs analog-to-digital conversion on the amplified voltage signal to obtains a digital signal, and outputs the digital signal to the processing unit.

5. The current measurement system of claim 3, wherein the voltage generating unit comprises a plurality of switch controlling modules, and the switch controlling modules are electrically coupled to the controlling unit.

6. The current measurement system of claim 5, wherein the switch controlling module comprises a switch, a first terminal of the switch is electrically coupled to the controlling unit, a second terminal of the switch is electrically coupled to the current input terminal and the voltage obtaining unit, and a third terminal of the switch is electrically coupled to the voltage obtaining unit.

7. The current measurement system of claim 6, wherein the switch controlling module comprises a resistor, a first terminal of the resistor is electrically coupled to the second terminal of the switch, and a second terminal of the resistor is electrically coupled to the third terminal of the switch.

8. The current measurement system of claim 6, wherein the switch is a field effect transistor (FET).

9. The current measurement system of claim 8, wherein the first terminal of the switch is a gate of the FET, the second terminal of the switch is a drain of the FET, and the third terminal of the switch is a source of the FET.

10. The current measurement system of claim 1, wherein the processing unit comprises a human-computer interface platform and a computer.

11. A current measurement system configured for measuring current at a current input terminal, comprising:
a controlling unit outputting a control signal;
a voltage generating unit coupling the controlling unit and the current input terminal; wherein the voltage generating unit receives the control signal, and converts the current into different voltage signals;
a voltage obtaining unit coupling the voltage generating unit and obtaining the voltage signals from the voltage generating unit;
a voltage amplifying unit coupling the voltage obtaining unit, and amplifying the voltage signals by a preset coefficient to obtain an amplified voltage signal; and
a converting unit coupling between the voltage amplifying unit and performing analog-to-digital conversion on the amplified voltage signal to obtains a digital signal, and outputting the digital signal; and
a processing unit coupling the converting unit and converting the digital signal to obtain a corresponding value of current.

12. The current measurement system of claim 11, wherein the voltage generating unit comprises a plurality of switch controlling modules, and the switch controlling modules are electrically coupled to the controlling unit.

13. The current measurement system of claim 12, wherein the switch controlling module comprises a switch, a first terminal of the switch is electrically coupled to the controlling unit, a second terminal of the switch is electrically coupled to the current input terminal and the voltage obtaining unit, and a third terminal of the switch is electrically coupled to the voltage obtaining unit.

14. The current measurement system of claim 13, wherein the switch controlling module comprises a resistor, a first terminal of the resistor is electrically coupled to the second terminal of the switch, and a second terminal of the resistor is electrically coupled to the third terminal of the switch.

15. The current measurement system of claim 13, wherein the switch is a field effect transistor (FET).

16. The current measurement system of claim 13, wherein the first terminal of the switch is a gate of the FET, the second terminal of the switch is a drain of the FET, and the third terminal of the switch is a source of the FET.

17. The current measurement system of claim 11, wherein the processing unit comprises a human-computer interface platform and a computer.
